(19) United States
(12) Patent Application Publication
(10) Pub. No.: US 2018/0031607 A1
(43) Pub. Date: Feb. 1, 2018

(54) COMMON BOARD OF AN ADAPTOR FOR A TESTER, ADAPTOR FOR A TESTER, AND TESTER INCLUDING THE COMMON BOARD

(71) Applicant: Samsung Electronics Co., Ltd., Suwon-si (KR)

(72) Inventors: Yong-Chul JANG, Asan-si (KR); Hee-Jung SHIN, Cheonan-si (KR)

(21) Appl. No.: 15/447,084

(22) Filed: Mar. 1, 2017

(30) Foreign Application Priority Data
Jul. 28, 2016 (KR) 10-2016-0095973

(51) Int. Cl. G01R 1/073; G01R 31/28; H01R 31/06

(52) U.S. Cl. CPC G01R 1/07378; H01R 31/06; G01R 31/2831; H01R 2201/20

(57) ABSTRACT

A common board of an adaptor for a tester may include a common insulating plate, a common test signal line, a common power line, and a common ground line. The common test signal line may be arranged in the common insulating plate to provide at least one object with a test signal. The common power line may be arranged in the common insulating plate to provide the object with power. The common ground line may be arranged in the common insulating plate to ground the object. Therefore, when one kind of object may be changed into other different kinds of objects, only the adapting board may be replaced with a new adapting board corresponding to the other kinds of the objects without changing of the entire adaptor.

### CROSS-RELATED APPLICATION

This application claims priority under 35 USC §119 to Korean Patent Application No. 10-2016-0095973, filed on Jul. 28, 2016 in the Korean Intellectual Property Office (KIPO), the contents of which are herein incorporated by reference in their entirety.

### BACKGROUND

### 1. Field

Example embodiments relate to a common board of an adaptor for a tester, an adaptor for a tester including the common board, and a tester including the common board. More particularly, example embodiments relate to a common board of an adaptor for a tester that may be used for testing different kinds of objects, an adaptor for a tester including the common board, and a tester including the common board.

### 2. Description of the Related Art

Generally, a tester may be used for testing electrical characteristics of a semiconductor package. The tester may include a test head and an adaptor. The test head may be configured to generate test signals. The adaptor may be electrically connected with the test head. A plurality of semiconductor packages may be mounted on the adaptor.

According to related arts, the adaptor may include conductive lines corresponding to external terminals of the semiconductor package. Thus, when one kind of semiconductor package is changed into other kinds of new semiconductor packages, the adaptor may be replaced with a new adaptor including conductive lines that may correspond to external terminals of the new semiconductor package, thereby increasing the cost for manufacturing the adaptor. Further, as the semiconductor package may be highly integrated, noise may be generated between the adjacent semiconductor packages on the adaptor. The noise may result in a reduction of reliability of test results.

### SUMMARY

Example embodiments provide a common board that may be commonly used for testing objects regardless of different kinds of objects attached thereto.

Example embodiments also provide an adaptor for a tester including the above-mentioned common board that may be capable of reducing noise.

Example embodiments still also provide a tester including the above-mentioned common board.

According to example embodiments, there may be provided a common board of an adaptor for a tester. The common board may include a common insulating plate, a common test signal line, a common power line, and a common ground line. The common test signal line may be arranged in the common insulating plate to provide at least one object with a test signal. The common power line may be arranged in the common insulating plate to provide the at least one object with power. The common ground line may be arranged in the common insulating plate to ground the at least one object.

According to example embodiments, there may be provided an adaptor for a tester. The adaptor may include a common board and an adapting board. The common board may be configured to receive a test signal for testing at least one object. The adapting board may be detachably connected with the common board. The adapting board may be electrically connected with the at least one object to transmit the test signal to the at least one object.

According to example embodiments, there may be provided an adaptor for a tester. The adaptor may include an insulating plate, a test signal line, a power line, and a ground line. The test signal line may be arranged in the insulating plate to provide at least one object with a test signal. The power line may be arranged in the insulating plate to provide the at least one object with power. The power line may have an electromagnetic band gap (EBG) structure. The ground line may be arranged in the insulating plate to ground the at least one object.

According to example embodiments, there may be provided an adaptor for a tester. The adaptor may include an insulating plate, a test signal line, a power line, and a ground line. The test signal line may be arranged in the insulating plate to provide at least one object with a test signal. The power line may be arranged in the insulating plate to provide the at least one object with power. The ground line may be arranged in the common insulating plate to ground the at least one object. The ground line may have an electromagnetic band gap (EBG) structure.

According to example embodiments, there may be provided a tester. The tester may include a test head and an adaptor. The test head may be configured to generate a test signal for testing at least one object. The adaptor may include a common board and an adapting board. The common board may be configured to receive a test signal for testing at least one object. The adapting board may be detachably connected with the common board. The adapting board may be electrically connected with the at least one object to transmit the test signal to the at least one object.

According to example embodiments, the adaptor may include the common board and the adapting board separated from the common board. Further, the adapting board may be detachably connected with the common board.

### BRIEF DESCRIPTION OF THE DRAWINGS

Example embodiments will be more clearly understood from the following detailed description taken in conjunction with the accompanying drawings. FIGS. 1A to 14 represent non-limiting, example embodiments as described herein.

FIG. 1A is an example block diagram illustrating a tester in accordance with example embodiments;

FIG. 1B is a front view illustrating the tester in accordance with example embodiments;

FIG. 2 is a perspective view illustrating an interface unit of the tester in FIG. 1;

FIG. 3 is an enlarged exploded perspective view of a portion III of the interface unit in FIG. 2;

FIG. 4 is an enlarged cross-sectional view illustrating an adaptor in FIG. 3;

FIG. 5 is a cross-sectional view illustrating an adaptor in accordance with example embodiments;

FIG. 6 is an enlarged cross-sectional view illustrating a common ground line in FIG. 5;

FIG. 7 is a plan view illustrating the common ground line in FIG. 6;

FIG. 8 is a cross-sectional view illustrating an adaptor in accordance with example embodiments;

FIG. 9 is an enlarged cross-sectional view illustrating a common power line in FIG. 8;

FIG. 10 is a plan view illustrating the common power line in FIG. 9;

FIG. 11 is a cross-sectional view illustrating an adaptor in accordance with example embodiments;

FIG. 12 is a cross-sectional view illustrating an adaptor in accordance with example embodiments;

FIG. 13 is a cross-sectional view illustrating an adaptor in accordance with example embodiments; and

FIG. 14 is a cross-sectional view illustrating an adaptor in accordance with example embodiments.

### DETAILED DESCRIPTION OF THE EMBODIMENTS

Hereinafter, example embodiments will be explained in detail with reference to the accompanying drawings.

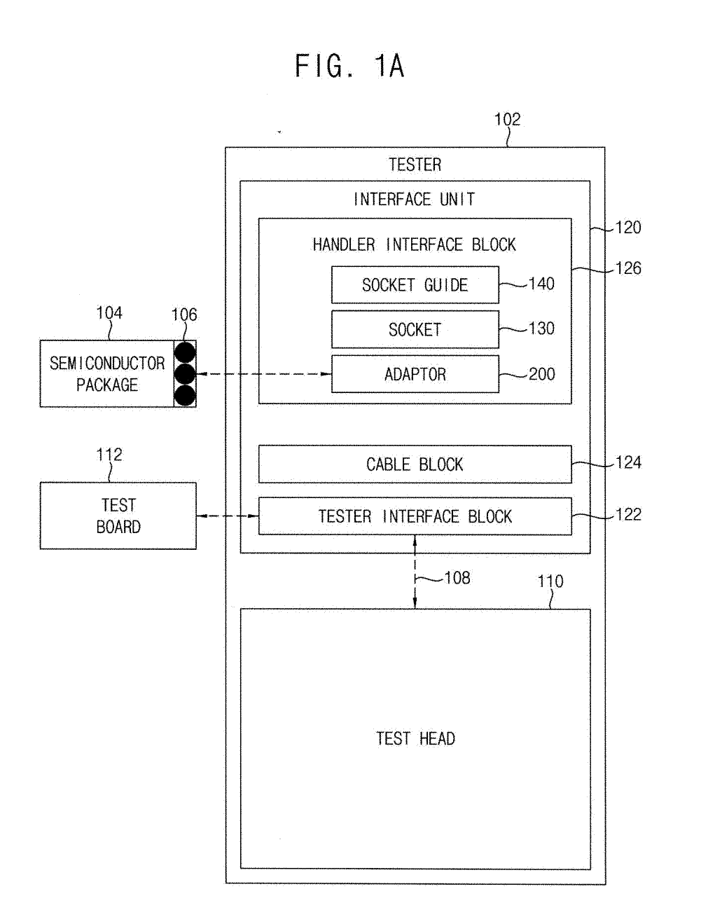

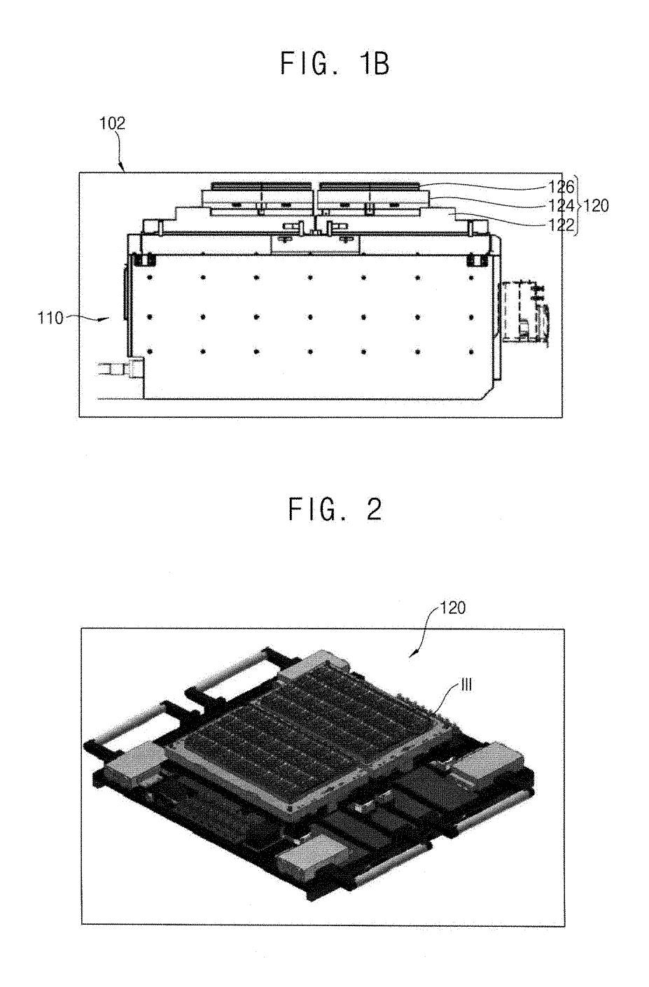

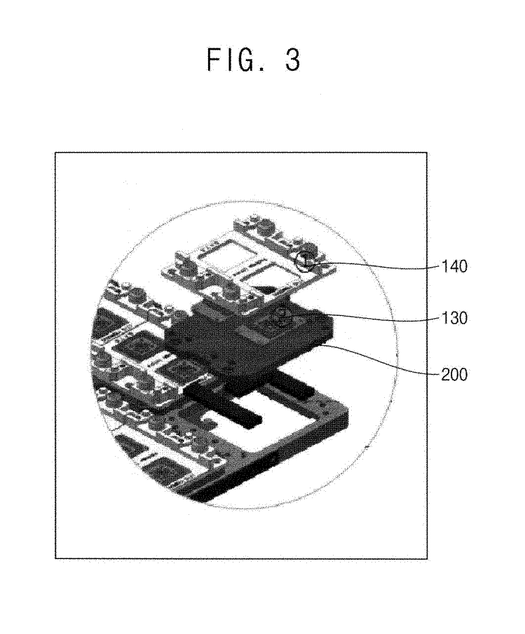

FIG. 1A is an example block diagram illustrating a tester in accordance with example embodiments. FIG. 1B is a front view illustrating a tester in accordance with example embodiments. FIG. 2 is a perspective view illustrating an interface unit of the tester in FIGS. 1A and 1B. FIG. 3 is an enlarged exploded perspective view of a portion III of the interface unit in FIG. 2.

Referring to FIGS. 1A to 3, a tester 102 of this example embodiment may include a test head 110 and an interface unit 120. In some example embodiments, the tester 102 may test electrical characteristics of objects such as semiconductor packages (e.g., 104). Each of the semiconductor packages may include one or more external terminals 106 such as solder balls. Alternatively, the tester 102 may be used for testing other electronic device as well as the semiconductor packages 104.

The test head 110 may be configured to generate a test signal 108 for testing the semiconductor packages 104. The test signal 108 may be supplied to the external terminals 106 through the interface unit 120.

The interface unit 120 may be arranged over the test head 110. The interface unit 120 may be configured to transmit the test signal 108 generated from the test head 110 to the semiconductor packages 104. The interface unit 120 may have functions for electrically connecting various kinds of the semiconductor packages 104 with the test head 110. Thus, the external terminals 106 may be changed in accordance with the kinds of the semiconductor packages 104. The interface unit 120 may electrically connect the external terminals 106 of the semiconductor packages 104 with the test head 110.

The interface unit 120 may include a tester interface block 122, a cable block 124 and a handler interface block 126. The tester interface block 122 may be mounted on an upper surface of the test head 110. A test board 112 may be installed at the tester interface block 122. The test signal 108 may be transmitted to or otherwise inputted into the test board 112.

The cable block 124 may be arranged on an upper surface of the tester interface block 122. The cable block 124 may be configured to receive or otherwise fix cables of the tester 102. The handler interface block 126 may be arranged over the tester interface block 122. The handler interface block 126 may include an adaptor 200, a socket 130 and a socket guide 140.

The semiconductor package 104 may be arranged on an upper surface of the adaptor 200. The socket 130 may be configured to fix the semiconductor package 104 to the upper surface of the adaptor 200. The socket guide 140 may be configured to guide the semiconductor package 104 to a fixed position in the socket 130.

The semiconductor package 104 may be electrically connected with the test head 110 through the adaptor 200. The adaptor 200 may include conductive lines electrically connected to the external terminals 106 of the semiconductor package 104. Thus, when one kind of the semiconductor package 104 is changed into another different or new kind of semiconductor package 104, the conductive lines of the adaptor 200 may not be electrically connected or otherwise aligned with external terminals 106 of the new semiconductor package 104. In accordance with embodiments disclosed herein, only an adapting board of the adaptor 200 including arrangements corresponding to the external terminals 106 of the new semiconductor package 104 needs to be changed, rather than changing out the entire adaptor 200, as further described in detail below.

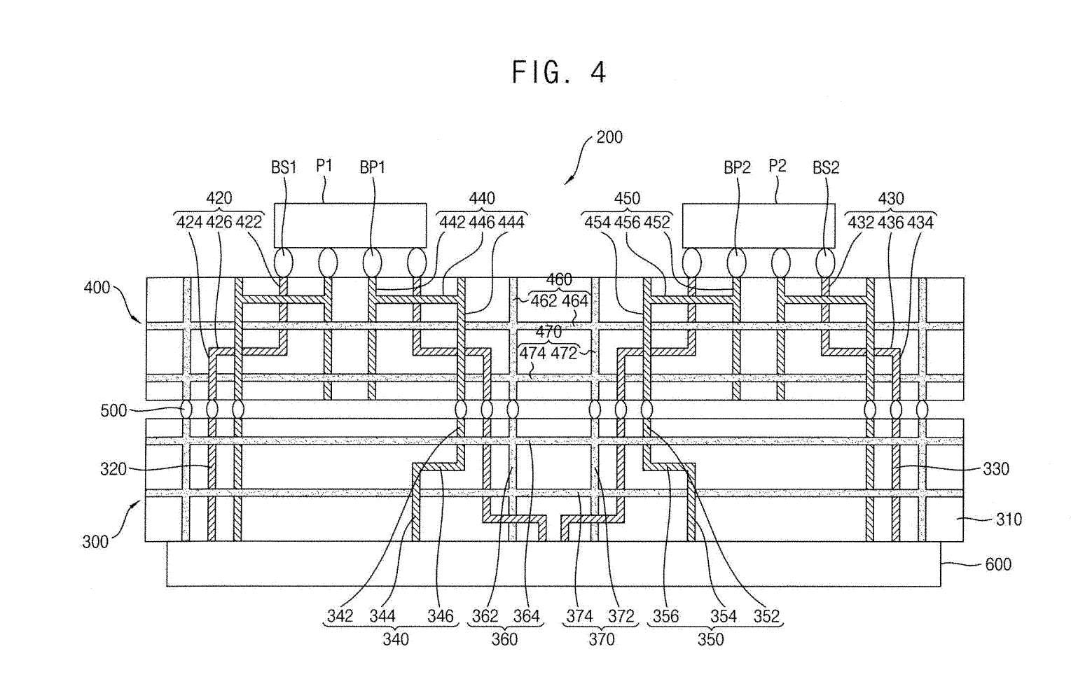

FIG. 4 is an enlarged cross-sectional view illustrating an adaptor 200 in FIG. 3. Referring to FIG. 4, the adaptor 200 of this example embodiment may include a common board 300 and an adapting board 400.

The common board 300 may be electrically connected with the test head 110. The common board 300 may be arranged on the test board (e.g., 112). In some example embodiments, the common board 300 may be continuously used without changing of the common board 300 regardless of there being different kinds of the semiconductor packages 104.

The adapting board 400 may be arranged over the common board 300. The adapting board 400 may be detachably connected to the common board 300. The adapting board 400 may be detachably connected to the common board 300 via conductive connecting members. In some example embodiments, the conductive connecting members may include conductive bumps 500. Alternatively, the conductive connecting members may include other members having an electrical connection function as well as the conductive bumps 500.

The adapting board 400 may include conductive patterns having arrangements that may correspond to the external terminals 106 of the semiconductor package 104. Thus, when one kind of the semiconductor package 104 may be changed into the new, different kind of semiconductor package 104, only the adapting board 400 may be changed into a new adapting board 400 including conductive patterns corresponding to the external terminals 106 of the new semiconductor package 104. The common board 300 need not be changed out and may continue to be used. As a result, a cost for manufacturing and maintaining the adaptor 200 in use is remarkably reduced.

In some example embodiments, a first semiconductor package P1 and a second semiconductor package P2 may be arranged on the adaptor 200. The test signal 108 of the test head 110 may be transmitted to the adaptor 200 through a connector 600. The connector 600 may be arranged on a lower surface of the common board 300. The first and second semiconductor packages P1 and P2 may be tested using the single connector 600. Alternatively, one semiconductor package or at least three semiconductor packages may be tested using the connector 600.

The common board 300 may include a common insulating plate 310, first and second common test signal lines 320 and 330, first and second common power lines 340 and 350 and first and second common ground lines 360 and 370. In some example embodiments, because the two semiconductor packages P1 and P2 may be tested using the single adaptor 200, the common board 300 may include the two common test signal lines 320 and 330, the two common power lines 340 and 350, and the two common ground lines 360 and 370. In some example embodiments, when at least three semiconductor packages may be tested using the adaptor 200, the common board 300 may include at least three common test signal lines, at least three common power lines, and at least three common ground lines.

The common insulating plate 310 may be arranged on the test board. The common insulating plate 310 may include an insulating material. The insulating material of the common insulating plate 310 may not be restricted within a specific material. In other words, the insulating material of the common insulating plate 310 may be any suitable insulating material.

The first common test signal line 320 may be configured to transmit the test signal to the first semiconductor package P1. The first common test signal line 320 may be vertically formed, or otherwise vertically disposed, in the common insulating plate 310. The first common test signal line 320 may have an upper end exposed through an upper surface of the common insulating plate 310, and a lower end exposed through a lower surface of the common insulating plate 310. The conductive bump 500 may be mounted on the upper end of the first common test signal line 320. The lower end of the first common test signal line 320 may be connected to the connector 600.

The second common test signal line 330 may be configured to transmit the test signal to the second semiconductor package P2. The second common test signal line 330 may be vertically formed, or otherwise vertically disposed, in the common insulating plate 310. The second common test signal line 330 may have an upper end exposed through an upper surface of the common insulating plate 310, and a lower end exposed through a lower surface of the common insulating plate 310. The conductive bump 500 may be mounted on the upper end of the second common test signal line 330. The lower end of the second common test signal line 330 may be connected to the connector 600.

The first common power line 340 may be configured to transmit power to the first semiconductor package P1. The first common power line 340 may include upper and lower vertical lines 342 and 344 vertically formed, or otherwise vertically disposed, in the common insulating plate 310, and a horizontal line 346 connected between a lower end of the upper vertical line 342 and an upper end of the lower vertical line 344. The upper vertical line 342 may be positioned closer to the first semiconductor package P1 compared to the lower vertical line 344. An upper end of the upper vertical line 342 may be exposed through the upper surface of the common insulating plate 310. A lower end of the lower vertical line 344 may be exposed through the lower surface of the common insulating plate 310. The conductive bump 500 may be mounted on the upper end of the upper vertical line 342. The lower end of the lower vertical line 344 may be connected to the connector 600.

The second common power line 350 may be configured to transmit the power to the second semiconductor package P2. The second common power line 350 may include upper and lower vertical lines 352 and 354 vertically formed, or otherwise vertically disposed, in the common insulating plate 310, and a horizontal line 356 connected between a lower end of the upper vertical line 352 and an upper end of the lower vertical line 354. The upper vertical line 352 may be positioned closer to the second semiconductor package P2 compared to the lower vertical line 354. An upper end of the upper vertical line 352 may be exposed through the upper surface of the common insulating plate 310. A lower end of the lower vertical line 354 may be exposed through the lower surface of the common insulating plate 310. The conductive bump 500 may be mounted on the upper end of the upper vertical line 352. The lower end of the lower vertical line 354 may be connected to the connector 600.

The first common ground line 360 may be configured to ground the first semiconductor package P1. The first common ground line 360 may include a vertical line 362 vertically formed, or otherwise vertically disposed, in the common insulating plate 310, and a horizontal line 364 horizontally arranged in the common insulating plate 310 to be intersected with the vertical line 362. The vertical line 362 may include an upper end exposed through the upper surface of the common insulating plate 310, and a lower end exposed through the lower surface of the common insulating plate 310. The conductive bump 500 may be mounted on the upper end of the vertical line 362. The lower end of the vertical line 362 may be connected to the connector 600.

The second common ground line 370 may be configured to ground the second semiconductor package P2. The second common ground line 370 may include a vertical line 372 vertically formed, or otherwise vertically disposed, in the common insulating plate 310, and a horizontal line 374 horizontally arranged in the common insulating plate 310 to be intersected with the vertical line 372. The vertical line 372 may include an upper end exposed through the upper surface of the common insulating plate 310, and a lower end exposed through the lower surface of the common insulating plate 310. The conductive bump 500 may be mounted on the upper end of the vertical line 372. The lower end of the vertical line 372 may be connected to the connector 600.

The adapting board 400 may include an adapting insulating plate 410, first and second adapting test signal lines 420 and 430, first and second adapting power lines 440 and 450, and first and second adapting ground lines 460 and 470. In some example embodiments, because the two semiconductor packages P1 and P2 may be tested using the single adaptor 200, the adapting board 400 may include the two adapting test signal lines 420 and 430, the two adapting power lines 440 and 450, and the two adapting ground lines 460 and 470. In some example embodiments, when at least three semiconductor packages may be tested using the adaptor 200, the adapting board 400 may include at least three common test signal lines, at least three common power lines, and at least three common ground lines.

The adapting insulating plate 410 may be arranged over the common board 310. The adapting insulating plate 410 may include an insulating material. The insulating material of the adapting insulating plate 410 may not be restricted within a specific material. In other words, the insulating material of the adapting insulating plate 410 may be any suitable insulating material.

The first adapting test signal line 420 may be configured to transmit the test signal to the first semiconductor package P1. The first adapting test signal line 420 may include upper and lower vertical lines 422 and 424 vertically formed, or otherwise vertically disposed, in the adapting insulating plate 410, and a horizontal line 426 connected between a lower end of the upper vertical line 422 and an upper end of the lower vertical line 424. An upper end of the upper vertical line 422 may be exposed through an upper surface of the adapting insulating plate 410. A lower end of the lower vertical line 424 may be exposed through a lower surface of the adapting insulating plate 410. The lower end of the lower vertical line 424 of the first adapting test signal line 420 may be electrically connected with the upper end of the first common test signal line 320 via the conductive bump 500. The upper end of the upper vertical line 422 of the first adapting test signal line 420 may be electrically connected with a signal terminal BS1 among the external terminals of the first semiconductor package P1.

The second adapting test signal line 430 may be configured to transmit the test signal to the second semiconductor package P2. The second adapting test signal line 430 may include upper and lower vertical lines 432 and 434 vertically formed, or otherwise vertically disposed, in the adapting insulating plate 410, and a horizontal line 436 connected between a lower end of the upper vertical line 432 and an upper end of the lower vertical line 434. An upper end of the upper vertical line 432 may be exposed through an upper surface of the adapting insulating plate 410. A lower end of the lower vertical line 434 may be exposed through a lower surface of the adapting insulating plate 410. The lower end of the lower vertical line 434 of the second adapting test signal line 430 may be electrically connected with the upper end of the second common test signal line 330 via the conductive bump 500. The upper end of the upper vertical line 432 of the second adapting test signal line 430 may be electrically connected with a signal terminal BS2 among the external terminals of the second semiconductor package P2.

The first adapting power line 440 may be configured to transmit the power to the first semiconductor package P1. The first adapting power line 440 may include inner and outer vertical lines 442 and 444 vertically formed, or otherwise vertically disposed, in the adapting insulating plate 410, and a horizontal line 446 connected between the inner vertical line 442 and the outer vertical line 444. An upper end of the inner vertical line 442 may be exposed through an upper surface of the adapting insulating plate 410. A lower end of the outer vertical line 444 may be exposed through a lower surface of the adapting insulating plate 410. The lower end of the outer vertical line 444 of the first adapting power line 440 may be electrically connected with the upper end of the upper vertical line 342 of the first common power line 340 via the conductive bump 500. The upper end of the inner vertical line 442 of the first adapting power line 440 may be electrically connected with a power terminal BP1 among the external terminals of the first semiconductor package P1.

The second adapting power line 450 may be configured to transmit the power to the second semiconductor package P2. The second adapting power line 450 may include inner and outer vertical lines 452 and 454 vertically formed, or otherwise vertically disposed, in the adapting insulating plate 410, and a horizontal line 456 connected between the inner vertical line 452 and the outer vertical line 454. An upper end of the inner vertical line 452 may be exposed through an upper surface of the adapting insulating plate 410. A lower end of the outer vertical line 454 may be exposed through a lower surface of the adapting insulating plate 410. The lower end of the outer vertical line 454 of the second adapting power line 450 may be electrically connected with the upper end of the upper vertical line 352 of the second common power line 350 via the conductive bump 500. The upper end of the inner vertical line 452 of the second adapting power line 450 may be electrically connected with a power terminal BP2 among the external terminals of the second semiconductor package P2.

The first adapting ground line 460 may be connected to the first common ground line 360 to ground the first semiconductor package P1. The first adapting ground line 460 may include a vertical line 462 vertically formed, or otherwise vertically disposed, in the adapting insulating plate 410, and a horizontal line 464 horizontally formed, or otherwise horizontally disposed, in the adapting insulating plate 410 to be intersected with the vertical line 462. The vertical line 462 may include an upper end exposed through the upper surface of the adapting insulating plate 410, and a lower end exposed through the lower surface of the adapting insulating plate 410. A lower end of the vertical line 462 of the first adapting ground line 460 may be electrically connected with the upper end of the vertical line 362 of the first common ground line 360 via the conductive bump 500.

The second adapting ground line 470 may be connected to the second common ground line 370 to ground the second semiconductor package P2. The second adapting ground line 470 may include a vertical line 472 vertically formed, or otherwise vertically disposed, in the adapting insulating plate 410, and a horizontal line 474 horizontally formed, or otherwise horizontally disposed, in the adapting insulating plate 410 to be intersected with the vertical line 472. The vertical line 472 may include an upper end exposed through the upper surface of the adapting insulating plate 410, and a lower end exposed through the lower surface of the adapting insulating plate 410. A lower end of the vertical line 472 of the second adapting ground line 470 may be electrically connected with the upper end of the vertical line 372 of the second common ground line 370 via the conductive bump 500.

The vertical lines of the common board 300 and the adapting board 400 may be formed by forming via holes through the common insulating plate 310 and the adapting insulating plate 410 using a drill, and by filling the via holes with a conductive material. Thus, the adapting board 400, which may be replaced by a new one in accordance with different kinds of the semiconductor packages, may have a thickness corresponding to a maximum depth of the via hole formed through the adapting board 400 using the drill.

When the thickness of the adapting board 400 may be greater than the maximum depth of the via hole using the drill, the adapting board 400 may be manufactured by attaching two boards to each other. When the thickness of the adapting board 400 may be relatively less than the maximum depth of the via hole using the drill, it may be difficult to arrange the test signal line, which may correspond to the external terminals of the semiconductor package, in the thin adapting board 400. Thus, the thickness of the adapting board 400 may correspond to a maximum depth of the via hole formed through the adapting board 400 using the drill.

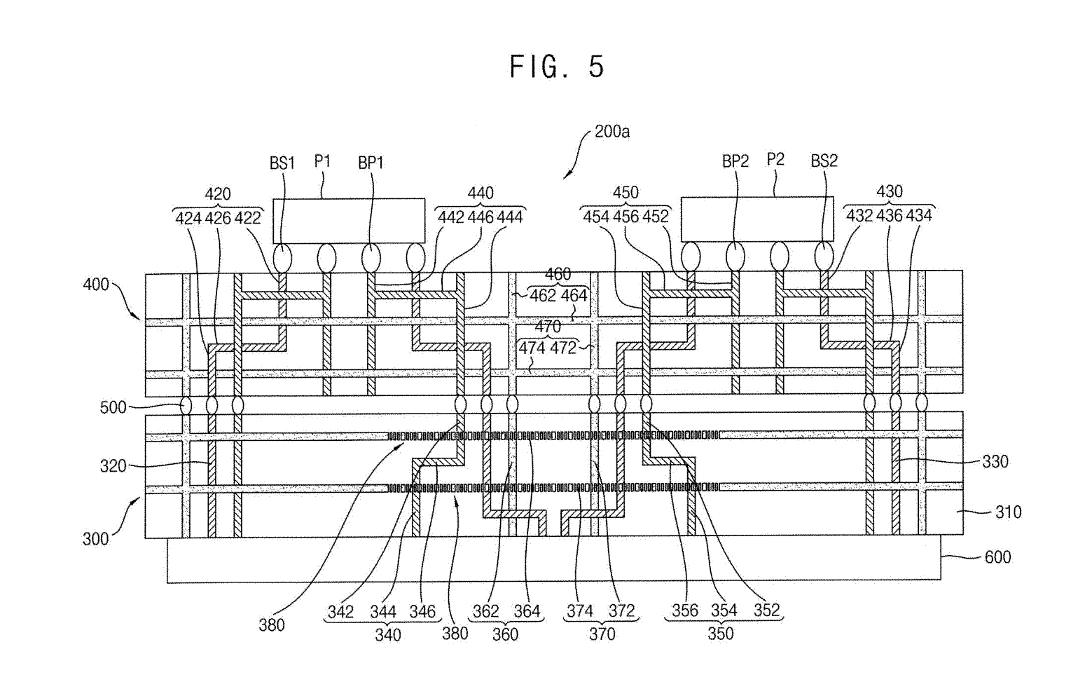

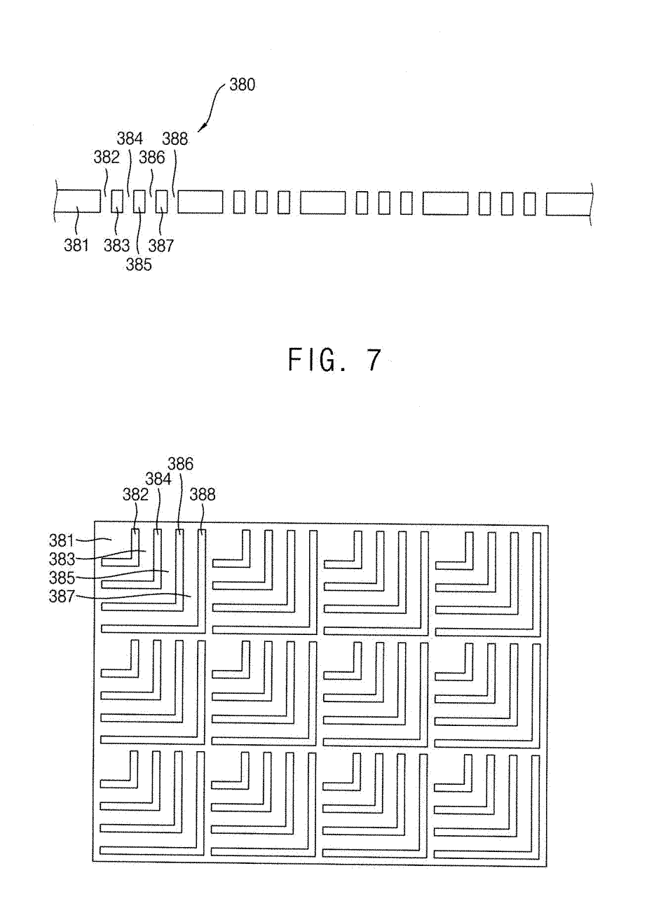

FIG. 5 is a cross-sectional view illustrating an adaptor in accordance with example embodiments. FIG. 6 is an enlarged cross-sectional view illustrating a common ground line in FIG. 5. FIG. 7 is a plan view illustrating the common ground line in FIG. 6. Reference is now made to FIGS. 5 to 7.

An adaptor 200a of this example embodiment may include elements substantially the same as those of the adaptor 200 in FIG. 4 except for a common ground line. Thus, the same reference numerals may refer to the same elements and any further explanations with respect to the same elements are not necessarily repeated for the sake of brevity.

While the first and second semiconductor packages P1 and P2 may be tested using the tester in FIG. 1, signal interference may be generated between the first and second semiconductor packages P1 and P2. Noise generated by the signal interference may decrease reliability of test results. A decoupling capacitor for reducing the noise may be mounted on the adaptor. In order to effectively reduce the noise, it may be required to arrange the decoupling capacitor at a position adjacent to the power line and the ground line. However, as the semiconductor package may be highly integrated, it may be very difficult to arrange the decoupling capacitor at the position adjacent to the power line and the ground line.

The adaptor 200a of this example embodiment may include an electromagnetic band gap (EBG) structure for reducing the noise. The EBG may reduce the noise by blocking a signal having a specific frequency band among high frequency bands using an LC resonance between the first and second semiconductor packages P1 and P2.

Referring to FIGS. 5 to 7, the EBG structure 380 may be provided to the common board 300 of the adaptor 200a. In some example embodiments, the EBG structure 380 may be formed at the first and second common ground lines 360 and 370 of the common board 300. Particularly, the EBG structure 380 may be formed at portions of the horizontal lines 364 and 374 of the first and second common ground lines 360 and 370 between the first and second semiconductor packages P1 and P2. Alternatively, the EBG structure 380 may be formed at the entire first and second common ground lines 360 and 370.

The EBG structure 380 may include a plurality of units repeatedly arranged in lengthwise and breadthwise directions. Each of the units of the EBG structure 380 may include at least one dielectric layer and conductive lines arranged at both sides of the dielectric layer. In other words, a conductive line may be arranged at each side of the dielectric layer. The dielectric layer and associated conductive lines include, or otherwise form, units that are repeatedly arranged in lengthwise and breadthwise directions.

In some example embodiments, the EBG structure 380 may include first to fourth conductive lines 381, 383, 385 and 387, and first to fourth dielectric layers 382, 384, 386 and 388. The first conductive line 381 and the second conductive line 383 may be arranged at both sides of the first dielectric layer 382. The second conductive line 383 and the third conductive line 385 may be arranged at both sides of the second dielectric layer 384. The third conductive line 385 and the fourth conductive line 387 may be arranged at both sides of the third dielectric layer 386. The fourth dielectric layer 388 may be arranged outside the fourth conductive line 387. A first conductive line of an adjacent EBG structure may be arranged outside the fourth dielectric layer 388. The fourth conductive line 387 may be electrically connected to the first conductive line of the adjacent EBG structure.

In some example embodiments, the first conductive line 381 may have a rectangular shape. The second conductive line 383 may have a shape spaced apart from adjacent two outer surfaces of the first conductive line 381 by a substantially same gap. For example, the second conductive line 383 may include two lines substantially perpendicular to each other. The third conductive line 385 may have a shape spaced apart from outer surfaces of the second conductive line 383 by a substantially same gap. For example, the shape of the third conductive line 385 may be an expanded shape of the second conductive line 383. The fourth conductive line 387 may have a shape spaced apart from outer surfaces of the third conductive line 385 by a substantially same gap. For example, the shape of the fourth conductive line 387 may be an expanded shape of the third conductive line 385. The first to fourth dielectric layers 382, 384, 386 and 388 may be parts of the common insulating plate 310.

Alternatively, the EBG structure 380 may have other shapes having the capacitor function as well as the above-mentioned structure.

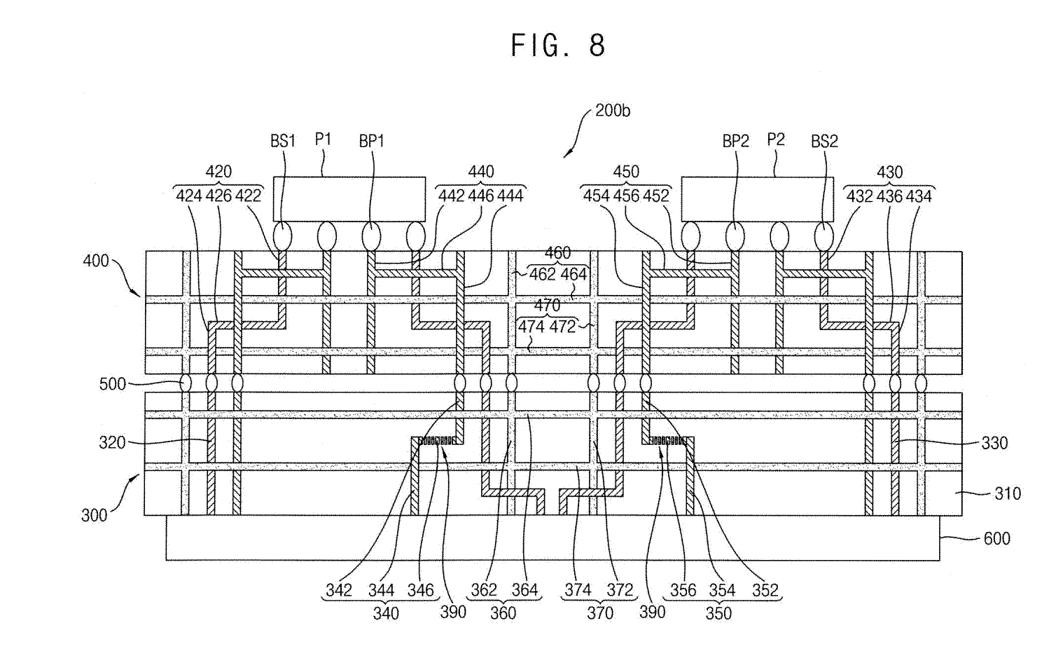

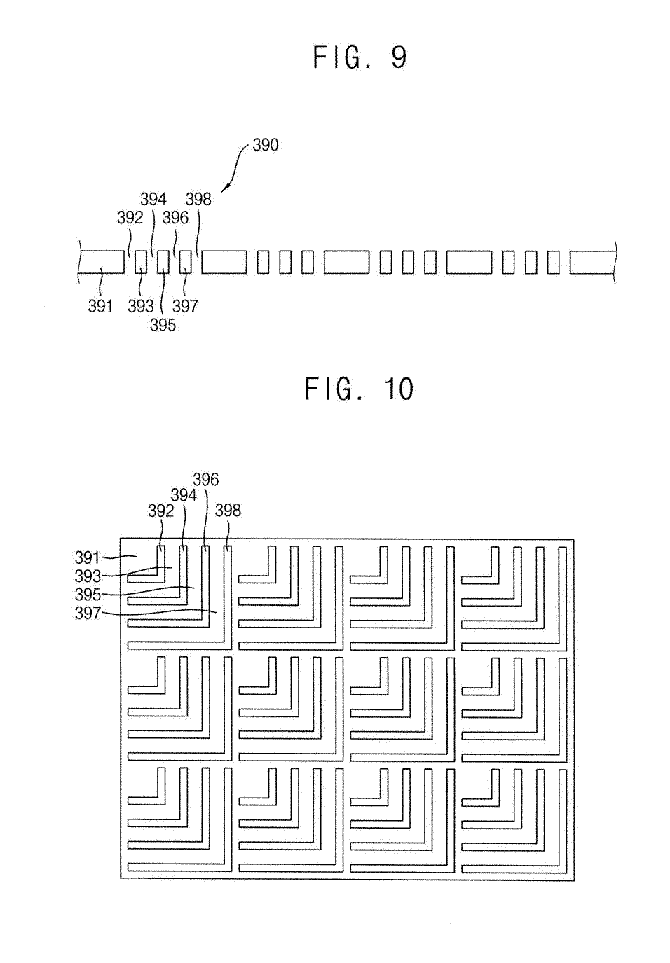

FIG. 8 is a cross-sectional view illustrating an adaptor in accordance with example embodiments. FIG. 9 is an enlarged cross-sectional view illustrating a common power line in FIG. 8. FIG. 10 is a plan view illustrating the common power line in FIG. 9. Reference is now made to FIGS. 8 to 10.

An adaptor 200b of this example embodiment may include elements substantially the same as those of the adaptor 200 in FIG. 4 except for a common power line. Thus, the same reference numerals may refer to the same elements and any further explanations with respect to the same elements are not necessarily repeated for the sake of brevity.

Referring to FIGS. 8 to 10, an EBG structure 390 may be provided to the first and second common power lines 340 and 350 of the common board 300. Particularly, the EBG structure 390 may be formed at portions of the horizontal lines 346 and 356 of the first and second common power lines 340 and 350 between the first and second semiconductor packages P1 and P2.

The EBG structure 390 may have a shape substantially similar to that of the EBG structure 380 in FIG. 7. Thus, the EBG structure 390 may include at least one dielectric layer and conductive lines arranged at both sides of the dielectric layer. In other words, a conductive line may be arranged at each side of the dielectric layer. The dielectric layer and associated conductive lines include, or otherwise form, units that are repeatedly arranged in lengthwise and breadthwise directions.

In some example embodiments, the EBG structure 390 may include first to fourth conductive lines 391, 393, 395 and 397, and first to fourth dielectric layers 392, 394, 396 and 398. The first conductive line 391 and the second conductive line 393 may be arranged at both sides of the first dielectric layer 392. The second conductive line 393 and the third conductive line 395 may be arranged at both sides of the second dielectric layer 394. The third conductive line 395 and the fourth conductive line 397 may be arranged at both sides of the third dielectric layer 396. The fourth dielectric layer 398 may be arranged outside the fourth conductive line 397. A first conductive line of an adjacent EBG structure may be arranged outside the fourth dielectric layer 398. The fourth conductive line 397 may be electrically connected to the first conductive line of the adjacent EBG structure.

In some example embodiments, the first conductive line 391 may have a rectangular shape. The second conductive line 393 may have a shape spaced apart from adjacent two outer surfaces of the first conductive line 391 by a substantially same gap. For example, the second conductive line 393 may include two lines substantially perpendicular to each other. The third conductive line 395 may have a shape spaced apart from outer surfaces of the second conductive line 393 by a substantially same gap. For example, the shape of the third conductive line 395 may be an expanded shape of the second conductive line 393. The fourth conductive line 397 may have a shape spaced apart from outer surfaces of the third conductive line 395 by a substantially same gap. For example, the shape of the fourth conductive line 397 may be an expanded shape of the third conductive line 395. The first to fourth dielectric layers 392, 394, 396 and 398 may be parts of the common insulating plate 310.

Alternatively, the EBG structure 390 may have other shapes having the capacitor function as well as the above-mentioned structure.

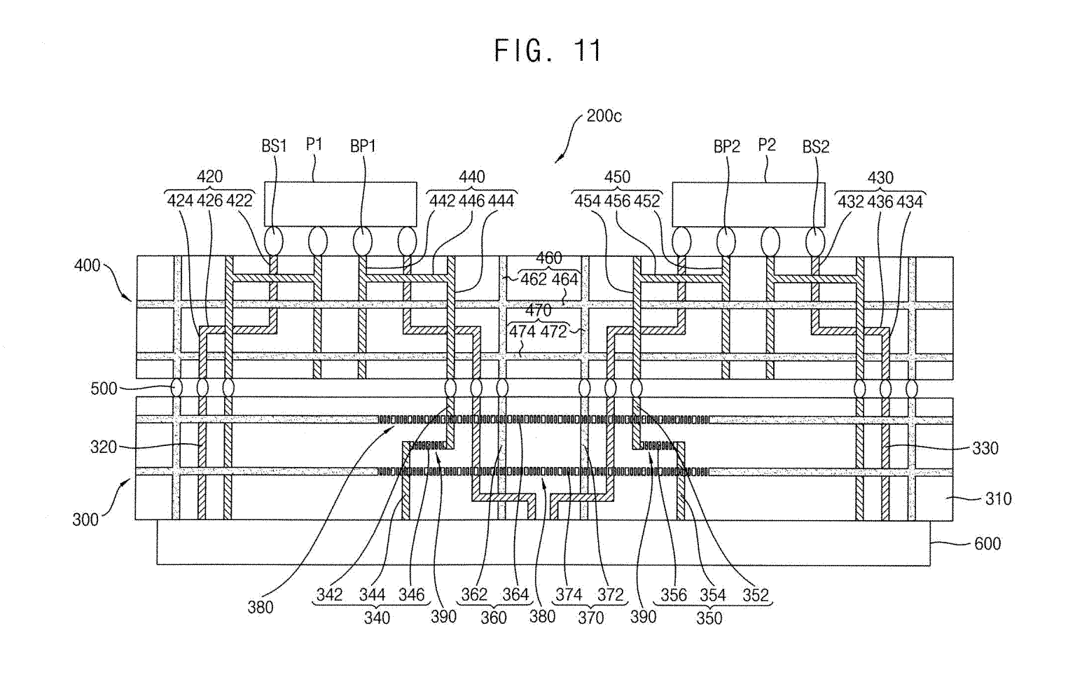

FIG. 11 is a cross-sectional view illustrating an adaptor in accordance with example embodiments.

An adaptor 200c of this example embodiment may include elements substantially the same as those of the adaptor 200 in FIG. 4 except for a common ground line and a common power line. Thus, the same reference numerals may refer to the same elements and any further explanations with respect to the same elements are not necessarily repeated herein for the sake of brevity.

Referring to FIG. 11, a first EBG structure 380 may be formed at the first and second common ground lines 360 and 370 of the common board 300. A second EBG structure 390 may be formed at the first and second common power lines 340 and 350 of the common board 300.

The first EBG structure 380 may have a shape substantially similar to that of the EBG structure 380 in FIG. 5. The second EBG structure 390 may have a shape substantially similar to that of the EBG structure 390 in FIG. 8. Thus, any further explanations with respect to the first and second EBG structures 380 and 390 are not repeated herein for the sake of brevity.

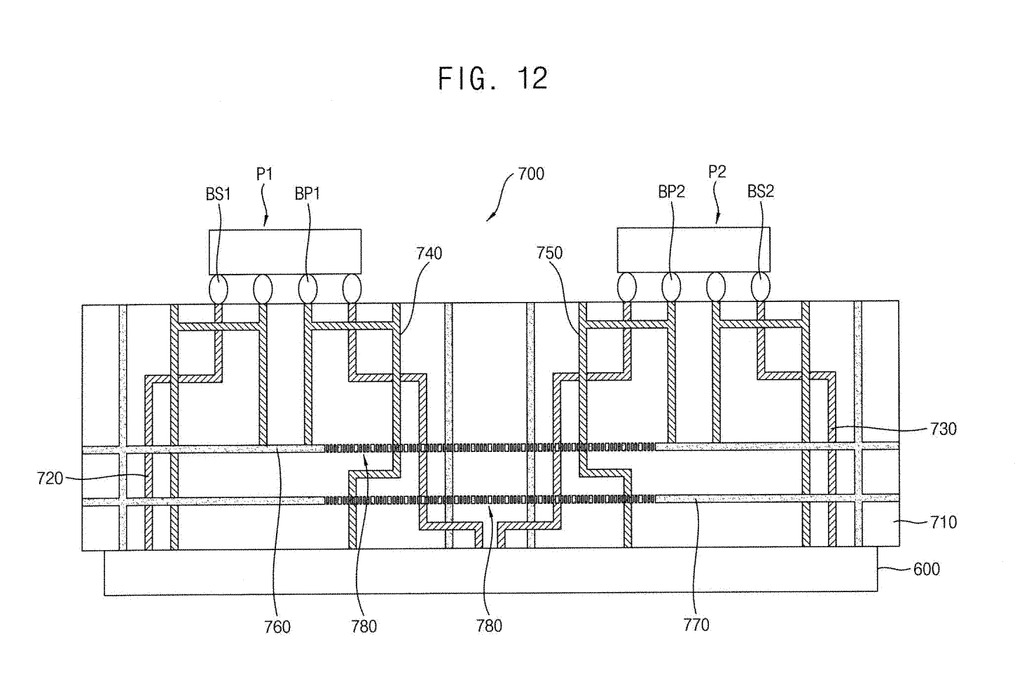

FIG. 12 is a cross-sectional view illustrating an adaptor in accordance with example embodiments. Referring to FIG. 12, an adaptor 700 of this example embodiment may include an insulating plate 710, first and second test signal lines 720 and 730, first and second power lines 740 and 750, and first and second ground lines 760 and 770.

The first and second test signal lines 720 and 730 may be arranged in the insulating plate 710 to transmit a test signal to the first and second semiconductor packages P1 and P2. The first and second power lines 740 and 750 may be arranged in the insulating plate 710 to transmit power to the first and second semiconductor packages P1 and P2. The first and second ground lines 760 and 770 may be arranged in the insulating plate 710 to ground the first and second semiconductor packages P1 and P2.

In some example embodiments, an EBG structure 780 may be provided to the first and second ground lines 760 and 770. Particularly, the EBG structure 780 may be formed at portions of vertical lines of the first and second ground lines 760 and 770 between the first and second semiconductor packages P1 and P2.

The EBG structure 780 may have a shape substantially the same as that of the EBG structure 380 in FIG. 5. Thus, any further explanations with respect to the EBG structure 780 are not repeated herein for the sake of brevity.

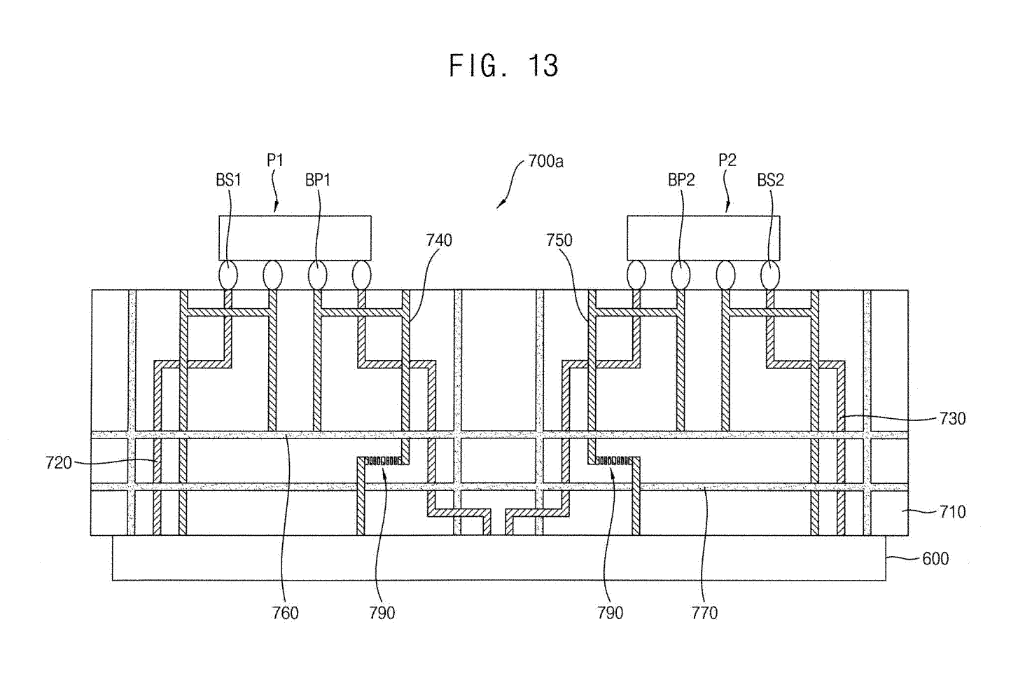

FIG. 13 is a cross-sectional view illustrating an adaptor in accordance with example embodiments. An adaptor 700a of this example embodiment may include elements substantially the same as those of the adaptor 700 in FIG. 12 except for a common power line. Thus, the same reference numerals may refer to the same elements and any further explanations with respect to the same elements are not repeated herein for the sake of brevity.

Referring to FIG. 13, an EBG structure 790 may be provided to the first and second common power lines 740 and 750. Particularly, the EBG structure 790 may be formed at portions of horizontal lines of the first and second common power lines 740 and 750 between the first and second semiconductor packages P1 and P2.

The EBG structure 790 may have a shape substantially the same as that of the EBG structure 380 in FIG. 8. Any further explanations with respect to the EBG structure 790 are note repeated herein for the sake of brevity.

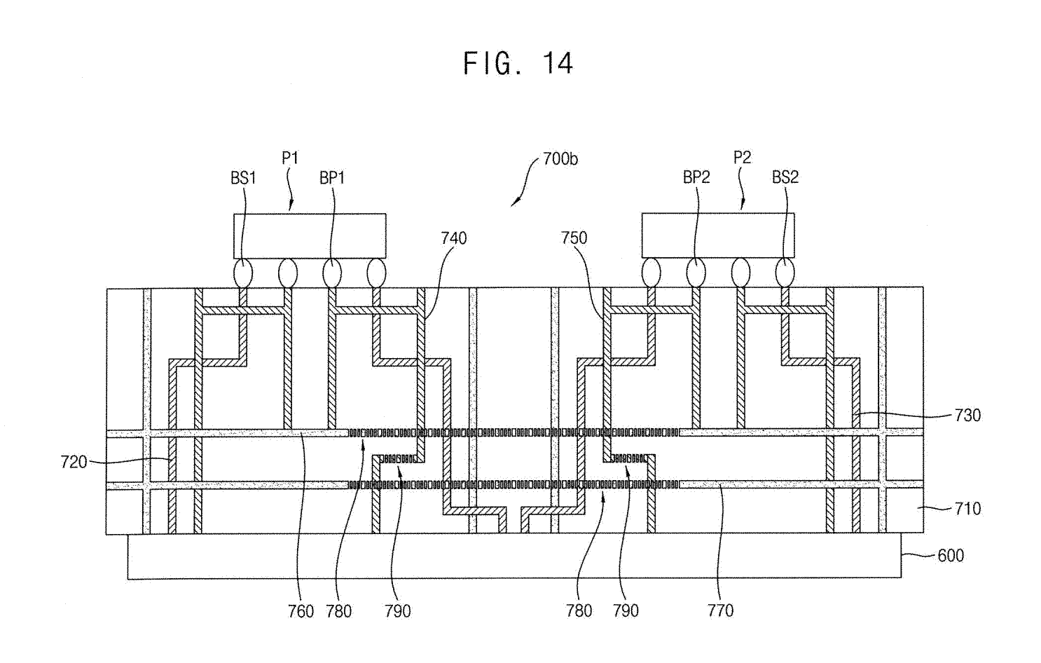

FIG. 14 is a cross-sectional view illustrating an adaptor in accordance with example embodiments. An adaptor 700b of this example embodiment may include elements substantially the same as those of the adaptor 700 in FIG. 12 except for a common ground line and a common power line. Thus, the same reference numerals may refer to the same elements and any further explanations with respect to the same elements is not repeated herein for the sake of brevity.

Referring to FIG. 14, a first EBG structure 780 may be formed at the first and second common ground lines 760 and 770. A second EBG structure 790 may be formed at the first and second common power lines 740 and 750.

The first EBG structure 780 may have a shape substantially similar to that of the EBG structure 780 in FIG. 12. The second EBG structure 790 may have a shape substantially similar to that of the EBG structure 790 in FIG. 12. Thus, any further explanations with respect to the first and second EBG structures 780 and 790 are not repeated herein for the sake of brevity.

According to example embodiments, the adaptor may include the common board and the adapting board separable from the common board. Further, the adapting board may be detachably connected with the common board. Therefore, when one kind of object may be changed into other different kinds of objects, only the adapting board may be replaced rather than the entire adapter, with a new adapting board corresponding to the other kinds of the objects without changing of the entire adaptor. As a result, the common board may still be used regardless of the different kinds of the objects, thereby decreasing the cost for manufacturing and/or maintaining the adaptor. Further, the common board may include one or more EGB structures to suppress noise between objects from being generated. As a result, reliability of test results is improved.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A common board of an adaptor for a tester, the common board comprising:
a common insulating plate;
a common test signal line arranged in the common insulating plate to provide at least one object with a test signal;
a common power line arranged in the common insulating plate to provide the at least one object with power; and
a common ground line arranged in the common insulating plate to ground the at least one object.

2. The common board of claim 1, wherein the common power line comprises an electromagnetic band gap (EBG) structure.

3. The common board of claim 2, wherein the EBG structure comprises:
at least one dielectric layer; and
a conductive line arranged at each side of the at least one dielectric layer.

4. The common board of claim 3, wherein the at least one dielectric layer and associated conductive lines include units that are repeatedly arranged in lengthwise and breadthwise directions.

5. The common board of claim 3, wherein the at least one dielectric layer is a part of the common insulating plate.

6. The common board of claim 1, wherein the common ground line comprises an electromagnetic band gap (EBG) structure.

7. The common board of claim 6, wherein the EBG structure comprises:
at least one dielectric layer; and
a conductive line arranged at each side of the at least one dielectric layer.

8. The common board of claim 7, wherein the at least one dielectric layer and associated conductive lines include units that are repeatedly arranged in lengthwise and breadthwise directions.

9. The common board of claim 7, wherein the at least one dielectric layer is a part of the common insulating plate.

10. The common board of claim 1, wherein the common power line and the common ground line comprise an electromagnetic band gap (EBG) structure.

11. An adaptor for a tester, the adaptor comprising:
a common board configured to receive a test signal for testing at least one object; and
an adapting board detachably connected with the common board, the adapting board electrically connected with the at least one object to transmit the test signal to the at least one object.

12. The adaptor of claim 11, further comprising a conductive bump interposed between the common board and the adapting board to electrically connect the common board with the adapting board.

13. The adaptor of claim 11, wherein the common board comprises:
a common insulating plate;
a common test signal line arranged in the common insulating plate and electrically connected with the adapting board to provide the adapting board with the test signal;
a common power line arranged in the common insulating plate and electrically connected with the adapting board to provide the at least one object with power; and
a common ground line arranged in the common insulating plate and electrically connected with the adapting board to ground the at least one object.

14. The adaptor of claim 13, wherein the common power line comprises an electromagnetic band gap (EBG) structure.

15-17. (canceled)

18. The adaptor of claim 13, wherein the common ground line comprises an electromagnetic band gap (EBG) structure.

19-21. (canceled)

22. The adaptor of claim 11, wherein the common power line and the common ground line comprise an electromagnetic band gap (EBG) structure.

23. The adaptor of claim 11, wherein the adapting board comprises:
an adapting insulating plate;
an adapting test signal line arranged in the adapting insulating plate and electrically connected with the common board to receive the test signal from the common board;
an adapting power line arranged in the adapting insulating plate and electrically connected with the common board to receive the power from the common board; and
an adapting ground line arranged in the adapting insulating plate and electrically connected with the common board to ground the at least one object.

24. An adaptor for a tester, the adaptor comprising:
an insulating plate;
a test signal line arranged in the insulating plate to provide at least one object with a test signal;
a power line arranged in the insulating plate to provide the at least one object with power, the power line having an EBG structure; and
a ground line arranged in the insulating plate to ground the at least one object.

25. The adaptor of claim 24, wherein the EBG structure comprises:
at least one dielectric layer; and
a conductive line arranged at each side of the at least one dielectric layer.

26. (canceled)

27. The adaptor of claim 24, wherein the common ground line comprises an electromagnetic band gap (EBG) structure.

28-36. (canceled)
